(19) United States
(12) Patent Application Publication
(10) Pub. No.: US 2020/0147527 A1
(43) Pub. Date: May 14, 2020

(54) WBC FILTER AND FABRICATING METHOD THEREOF

(71) Applicant: Cheng-Hsien Liu, Hsinchu City (TW)

(72) Inventors: Cheng-Hsien LIU, Hsinchu City (TW); Chung-Yu CHOU, Taichung City (TW); Po-Chen SHIH, Hsinchu City (TW); Yu-Shuang LEE, Taoyuan City (TW); Fan-Yun HUANG, Hsinchu County (TW); Chia-Ming CHANG, Taipei City (TW); Meng-Ping LU, Taoyuan City (TW)

(21) Appl. No.: 16/185,703

(22) Filed: Nov. 9, 2018

(51) Int. Cl. B01D 29/44; G03F 7/038; G03F 7/20; B01D 29/00

(52) U.S. Cl. CPC B01D 29/44; B01D 29/0093; G03F 7/20; G03F 7/038

(57) ABSTRACT

We provide a WBC filter which comprises an input unit including two entrances, a first end means for injecting a whole blood and a buffer solution; a passage which a third end connects the second end of the entrance, wherein pluralities of pillars constructed in the passage; and an output unit connects to a fourth end of the passage, means for conducting a screened liquid and a purified liquid; wherein the whole blood and the buffer solution are introduced into the passage from the entrance by a driving force, and forms buffer solution laminar and waste liquid laminar; a large-size blood cells at the buffer solution laminar are lysed to form particulates by the red blood cell lysis buffer, and move toward a second side, thus enter the waste liquid laminar; and conducts the buffer solution laminar, whereby filters a purified liquid containing large amount of white blood cells.

### FIELD OF THE INVENTION

The present invention relates to a blood cell filter, particularly, a blood cell filter for screening white blood cells.

### BACKGROUND OF THE INVENTION

Clinically, infections are caused by pathogens during surgery or other medical procedures of chronic disease. Without appropriate care and early detection, these infections often cause severe sepsis, which threatens the life of patient. Sepsis is a disease resulted from pathogen invading the circulation, and the body's response to infection causes acute systemic infection. In order to defend external infections, such as microbes invading from lung or skin, the immune system accelerates the release of many white blood cells into blood, and it thus induces systemic inflammation and causes injury to the cells. Based on this mechanism, the diagnosis of sepsis often relies on blood test, and counting white blood cells of the suspected patients is a major way to diagnose sepsis, which helps doctors to determine whether the suspected patients is suffering from sepsis.

In common medical facility, the way of testing white blood cells is conducted by applying blood samples of the suspected patient to sensors having a microfluidic channel. For example, Chinese Patent Publication No. 103403547 discloses a microfluidic channel element for capturing white blood cells from blood samples, wherein the microfluidic channel element comprises two injection ports, one output port and one microfluidic channel. One injection port is used for injecting washing buffer solution, and the other injection port is used for injecting blood sample from suspected patient (hereinafter “whole blood sample”). The function of this buffer solution is “washing” the whole blood sample, which means removing impurities from the whole blood sample. After the buffer solution and the whole blood sample are injected, the buffer solution and the whole blood sample mix in the forepart of the microfluidic channel, and then the mixture flows into the following part of the microfluidic channel to separate the red blood cells. Then, the sample obtained after red blood cells separation procedure continues to flow to next filter for subsequent process.

According to the patent document (CN103403547A), the separation procedure for red blood cells is described as follows. The surface of the microfluidic channel is coated with a capturing substance to capture red blood cells, and the microfluidic channel is designed in S shapes, as shown in the red blood cell capturing device in FIG. 1. The whole blood sample is injected into the injection port, and the red blood cells are captured by the S-shaped microfluidic channel coated with the capturing substance. The configuration or S-shape microfluidic channel increases the contact surface area between the whole blood sample and the microfluidic channel, and thus improves the efficiency of capturing red blood cells. Despite the efficiency of capturing red blood cells is improved by the S-shape configuration, there remains a lot of substances other than white blood cells, such as platelets, are not captured by the S-shape channel, and therefore there are still a lot of substances other than white blood cells remain in the blood samples.

Additionally, U.S. Pat. No. 8,034,230 discloses a microfluidic channel element for cell separation. The element has two microfluidic channels: one is used for passing specific cells from the blood sample, and the other is used for accumulating specific cells from the blood sample. According to this invention, the blood sample passes through a plurality of pillars to select cells of specific diameter. Nevertheless, the diameter of red blood cells in blood sample varies from person to person. However, the diameters of red blood cells vary from person to person, and the blood sample must be dipped into the buffer for 1 to 2 seconds (preprocessing), therefore the time of dipping is hard to control. Moreover, the dipping step would deteriorate the blood sample, and the diameters of the red blood cells become uneven to lessen the screening rate. When the blood sample is screened by using the microfluidic channel provided by this invention, the screening rate of white blood cells is around 70%.

Furthermore, there is another way to filter out white blood cells. First, the whole blood is mixed with the lysis buffer (used to lyse the red blood cells), and let the mixture stand for 3 to 5 seconds, so that the red blood cells in the whole blood will be lysed. Thus, a liquid having better uniformity of white blood cells is obtained. Filtering out the white blood cells in this way requires collection of large amounts of whole blood from the test subject. Some of the whole blood is aspirated using a dropper and then placed in the culture dish to form the whole blood cell sample. Finally, the lysis buffer is added and mixed with the whole blood by agitator to make these two kinds of solution mixed homogeneously. Hence, when this method is used, not only the collection of large amounts of whole blood hassles put physiological burden on test subject. More importantly, the method using culture dish and agitator makes the sample susceptible to contamination from contaminants such as dust or bacteria, and this method is time-consuming.

### SUMMARY OF THE INVENTION

This disclosure describes device for counting WBCs using a simple, low-cost device. We provides a WBC filter which comprises an input unit which includes two entrances, a first end means for injecting a whole blood and a buffer solution; a passage which a third end connects the second end of the entrance, wherein pluralities of pillars constructed in the passage; and an output unit connects to a fourth end of the passage, means for conducting a screened liquid and a purified liquid; wherein the whole blood and the buffer solution are introduced into the passage from the entrance by a driving force, and forms buffer solution laminar flow and waste liquid laminar flow; separates pluralities of large-size blood cells from the whole blood by colliding the pillars, thus the large-size blood cells enter the buffer solution laminar flow; the large-size blood cells at the buffer solution laminar flow are lysed to form particulates by the red blood cell lysis buffer, and move toward a second side, thus enter the waste liquid laminar flow; and conducts the buffer solution laminar flow, whereby filters a purified liquid containing large amount of white blood cells.

In certain implementations, the buffer solution is selected from the group consisting of the PBS or the RBC lysis buffer. Otherwise, the passage on the first plane is a rectangle which long side is in the range of about 15 mm to about 40 mm. pillar on the first plane is a circle which radius is 50 μm. Furthermore, the two centers in the two circles is distance between 80 μm.

In certain implementations, the WBC filter further comprising an arrangement angle which is in the range of about 2.8 degrees to about 3.3 degrees. As well, the laminar flow moves paralleled to the first direction.

In another aspect, we disclose a different types of the WBC filter which comprising: a whole-blood input unit means for injecting a whole blood; a second entrance, which adjacent to the whole-blood input unit, means for injecting a buffer solution; a first entrance, which adjacent to the second entrance, means for injecting a PBS; a passage which a third end connects the second end of the entrance, wherein pillars constructed in the passage; and an output unit connects to a fourth end of the passage, means for conduct the screened liquid and purified liquid; the whole blood and the buffer solution are introduced into the passage from the entrance by a driving force; and after pluralities of blood cells in the whole blood collides with the pillar, the blood cells which radius is larger than 8 μm move to a first side and forms a buffer solution laminar flow; a pluralities of large-size blood cells at the buffer solution laminar flow are lysed to form particulates by the red blood cell lysis buffer, and move toward a second side, then enter the waste liquid laminar flow; Finally, it conducts the buffer solution laminar flow, whereby filters the white blood cells in the whole blood.

According to our invention, the white blood cells are not separated from whole blood through centrifuge. The simple structure design of the pillar array is used to introduce the prepared buffer solution, and the only two steps of initial screening and major screening are further performed to precisely separate the white blood cells in the whole blood. The screening accuracy of the WBC filter is increased by 8% to 15% when compared with the conventional one. Furthermore, the small volume of the WBC filter makes it to be a portable device, so that the user can carry it by his/her side.

In another aspect, we present a method for manufacturing WBC filter which comprises the following steps: Obtained a silicon wafer and coated a negative photoresist on the silicon wafer, Patterned the negative photoresist to obtain a first pattern; Coated the PDMS on the first pattern then harden the PDMS to form the CONCRETE PDMS which included a pillar array; Separated the CONCRETE PDMS from the silicon wafer; Bonded the CONCRETE PDMS to a glass substrate and formed The WBC filter.

In certain implementations, the critical dimension in the pillar array is 30 μm. In addition, the pillar having an aspect ratio which is in the range of about 2:1 to about 3:1.

According to our invention, it is easy to finish the WBC filter, and is cheap to get the WBC filter. The device is disposable and avoids the risk of infection of other people caused by repeated use. Moreover, the completed WBC filter is rigid and not easily broken and has no additional burden on the human body during the test procedure. Additionally, the pillar in the WBC filter also have high density and small spacing distance, and thus increase the capture rate of white blood cells and make the WBC filter is economical.

### BRIEF DESCRIPTION OF THE DRAWINGS

The present invention will be apparent to those skilled in the art by reading the following description of a preferred embodiment thereof with reference to the drawings, in which:

FIG. 1 is a schematic view of the conventional red blood cell capturing device;

FIG. 2 is a top plane view on the first plane of the WBC filter of the first embodiment of the present invention;

FIG. 3 is a partial view on the first plane of the WBC filter of the first embodiment of the present invention;

FIG. 4 is a partial view on the second plane of the WBC filter of the first embodiment of the present invention;

FIG. 5 is a partial view on the first plane of the WBC filter of the first embodiment of the present invention;

FIG. 6(a) and FIG. 6(b) is a is a partial view on the first plane of the WBC filter of the first embodiment of the present invention;

FIG. 7 is line chart about the filter rate in WBC filter of the embodiments of the present invention;

FIG. 8 is a schematic view of the manufacturing the WBC filter; and

FIG. 9 is a flow chart of the manufacturing the WBC filter;

### DETAILED DESCRIPTION OF THE PREFERRED EMBODIMENT

The present invention relates to a microfluid channel. In the following detailed description of the preferred embodiments, the reference is made to the accompanying drawings which form a part hereof, and as shown by way of illustration specific embodiments in which the invention may be practiced. As such, the directional terminology is used for purposes of illustration and is in no way limiting the present invention. In our present invention, we calculate the white blood filter rate by the following steps: Firstly, we get a first WBC counts from the input unit of the WBC filter by one flow cytometry. Then we get a second WBC counts from the output unit of the WBC filter by the same flow cytometry. Lastly, first WBC counts divided by second WBC counts is the white blood filter rate.

In the present invention, the X-axis, the Y-axis and the Z-axis are in a Cartesian coordinate system and are a right-handed Cartesian coordinate system. The detailed directions of the X-axis, the Y-axis, and the Z-axis and the zero point are indicated in the context of the respective drawings, wherein the definition of the zero point is as shown in the figure, and the X-axial is the first direction, the Y-axial is the second direction and the Z-axial is the third direction. Further, the plane formed by the X-axis and the Y-axis is defined as a first plane, the plane formed by the Y-axis and the Z-axis is a second plane, and the plane formed by the X-axis and the Z-axis is a third plane.

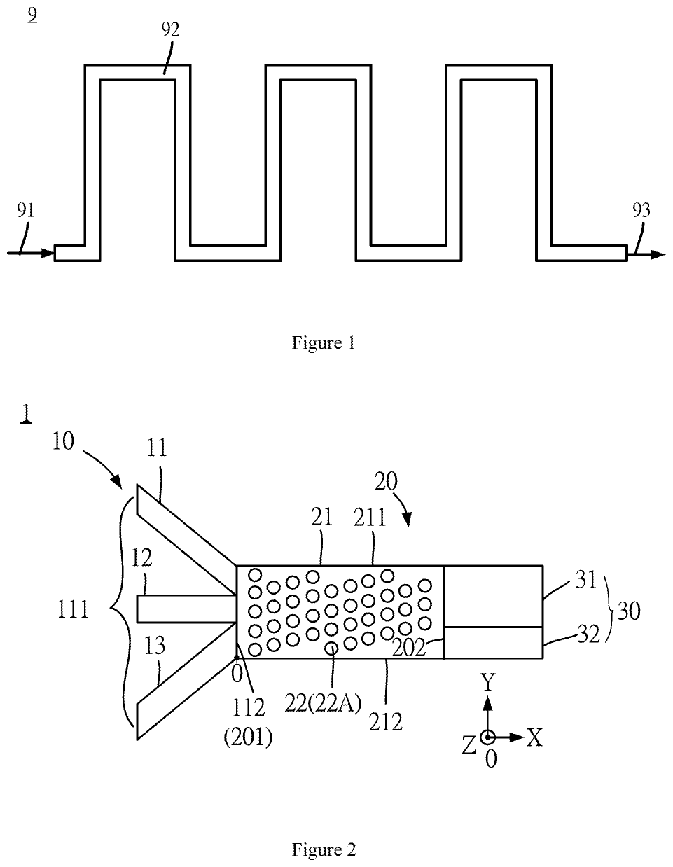

First, refer to FIG. 2, which is a diagram of the WBC filter (on the first plane) provided in the present invention. As shown in FIG. 2, the WBC filter 1 includes an input unit 10, a passage 20, and an output unit 30. The input unit 10 has two input ends: a first end 111 and a second end 112 opposite to the first end ill, wherein the first end 111 is used for injecting the whole blood and the buffer solution. The passage 20 also has two ends: a third end 201 and a fourth end 202 opposite to the third end 201, and two side ends: a first side 211 and a second side 212. The third end 201 is connected to the second end 112 of the entrance. Further, a pillar array 22 is configured in the passage 20. The output unit 30 is connected to the fourth end 202 of the passage 20 to conduct the screened liquid and purified liquid containing large amount of white blood cells, as well as the residual waste liquid after screening. The count of white blood cells in the purified liquid is more than that in the waste liquid. The output unit 30 has a first exit 31 and a second exit 32. And a zero point is defined at the second end 112 of the input unit 10.

Please further refer to FIG. 2. An embodiment illustrated in FIG. 2 is input unit 10 which has three entrances. As shown in FIG. 2, the three entrances are sequentially listed according to the descending y-axis values: first entrance 11, the second entrance 12, and the third entrance 13. The third entrance 13 is essential to constitute the WBC filter 1, because the whole blood of the test subject has to be infused into the WBC filter 1 via the third entrance 13 for analysis. In the present invention, the subject to be tested may be a healthy or ill person, which means the source of the whole blood is not limited to the patients. The first entrance 11 and the second entrance 12 can be chosen for practice, and preferably both of them are used for practice. The first entrance 11 and the second entrance 12 are used for infusing the buffer solution. In the embodiment of three entrances, the second entrance 12 have be infused with the buffer solution, and the rectangular structure of the second entrance 12 must be parallel to a first axis on the first plane to ensure the buffer solution contacts the whole blood.

Furthermore, in the present invention, one function of the buffer solution is to clean the whole passage 20, that is, to dissolve the dust or other substances in the blood which are unnecessary for analysis, such as blood lipids. Another function is to maintain the stability of the pH of the fluid in the passage 20 during the whole blood screening. In the present invention, the buffer solution is selected from the red blood cell lysis buffer, the phosphate solution, or the mixed solution of both the red blood cell lysis buffer and the phosphate solution. In this embodiment, the phosphate buffered saline (PBS, a kind of buffer solution for conventional biological use) is injected into the first exit 11 to clean the whole passage 20. Red blood cell (RBC) lysis buffer is injected into the second exit 12 to lyse the red blood cell (unnecessary for analysis) in the whole blood. In this embodiment, the RBC lysis buffer is formed by dissolving formic acid and saponin in deionized water, such that the RBC lysis buffer is capable of lysing red blood cells. When the RBC lysis buffer is formed by dissolving 0.11%-0.13% (v/v) formic acid and 0.04%-0.06% (w/v) saponin in deionized water, the RBC lysis buffer has better performance on lysing red blood cells.

Refer further to FIG. 2. In an embodiment illustrated by FIG. 2, the third end 201 of the passage 20 is connected to the second end 112 of the entrance, and the fourth end 202 of the passage 20 is connected to the output unit 30. By this configured connection, the fluidic channels for the whole blood and the buffer solution set in the WBC filter 1 are constructed. In the passage 20, the first exit 31 is neighbored and connected to the first side 211, and the second exit 32 is neighbored and connected to the second side 212. Furthermore, the passage 20 has a pillar array 22 composed of a plurality of pillars 22A. Therefore, when the first fluidic channel is viewed on the first plane, it is constructed by a plurality of pillars 22A and a rectangular substrate 21. The type of solution conducted by the first exit 31 and the second exit 32 is respectively determined depending on the location of the entrance. In this embodiment, when the whole blood is infused into the third entrance 13, the purified liquid flows out from the second exit 32, and the waste liquid flows out from the first exit 31. In another embodiment, when the whole blood is infused into the third entrance 11, the purified liquid flows out of the first exit 31, and the waste liquid flows out of the second exit 32. In this embodiment, when the waste liquid flows out of the first exit 31, the first exit 31 is connected to the waste recovery tank to collect the waste. When the purified liquid flows out of the second exit 32, the second exit 32 is connected to the detecting device or the screening device for subsequent analysis.

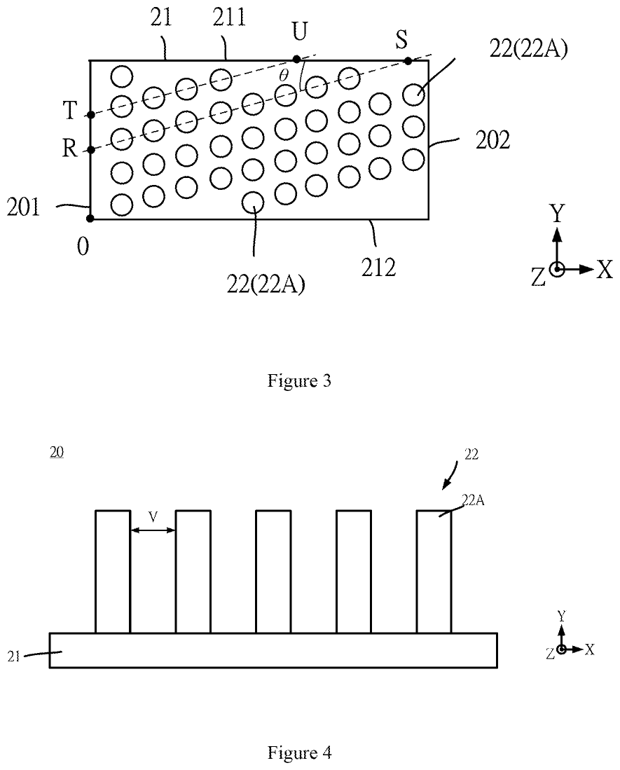

Next, please refer to FIG. 3 and FIG. 4. FIG. 3 is a partial view of the WBC filter 1 on the first plane. FIG. 4 is a partial view of the WBC filter 1 on a second plane. FIG. 3 and FIG. 4 show only the passage 20 of the WBC filter 1. Please refer to FIG. 3. As shown in FIG. 3, the pillar array 22 includes a passage 20 and a plurality of pillars 22A. The projection shape of the passage 20 on the first plane is a rectangle. The two long sides of the rectangle are the first side 211 and the second side 212 of the passage 20 respectively. The two short sides of the rectangle are the third end 201 and the fourth end 202 respectively. In this embodiment, the length of the long side can be configured to be 15 to 40 mm, the preferred design is 20 to 30 mm, and the best design is 25.5 mm. The best design which can makes the WBC filter rate reach 70%. In addition, the projection shape of each pillar 22A on the first plane is a circle having a diameter of 50 μm. It is equidistant from the projection shape (circle) center of any pillar 22A and projection shape center of the nearest pillar 22A, and the distance is 80 m. The pillar 22A are distributed throughout the passage 20. The allocation of pillar 22A starts from the first pillar 22A nearest to the zero point and is further distributed toward the +X direction and the second direction (i.e., Y-axis direction).

Next, please refer to FIG. 3 and refer back to FIG. 2. The point R in FIG. 3 is the center point of the third end 201. This R point and the center of the pillar 22A nearest to the R point in the pillar array 22 form an imaginary extension line, and the extension line extends toward the first side 211 to cross the first side 211 at the point S. The line segment RS passes through the center of many pillar 22A, as shown in FIG. 3. Those eight pillar 22A being crossed with RS line segment at their centers constitute a sequence of the pillar array 22. When the entire RS segment is shifted toward the +Y direction, a TU line segment is formed. The TU line segment passes through four pillar 22A. These four pillar 22A form another sequence of the pillar array 22. As shown in FIG. 3, when the entire RS line segment is further shifted toward the +Y direction or the −Y direction, the pillar 22A crossed by RS line segment form a sequence. Therefore, the centers of pillar 22A arrayed in the same sequence forms a line of centers. In the pillar array 22, all lines of center of sequence are parallel to each other.

Please further refer to FIG. 3. The sharp angle θ between the RS line segment and the first side 211 is referred to as an arrangement angle. The arrangement angle represents the layout of the pillar array 22. By properly designing this arrangement angle, the best screening rate of white blood cells can be obtained. The arrangement angle can be configured to be 2.8 to 3.3 degrees, so that the screening rate of white blood cells using the microfluidic channel provided by the invention reaches 70% or more. The optimal configuration of arrangement angle θ is 3 degrees, and the resultant optimal screening rate reaches 83% to 85%. Additionally, the liquid flowed out from the first exit 31 are closely related to the intersections of the RS line segment. In this embodiment, the RS line segment intersects the first side 211, so that a purified liquid flow is conducted by the first exit 31. In another embodiment, the RS line segment intersects the second side 212 rather than the first side 211, and therefore the waste liquid flow is conducted by the first exit 31.

Please further refer to FIG. 4. As shown in FIG. 4, on the second plane, the pillar 22A are arranged along the first direction to form the pillar array 22, and each single pillar 22A is configured to extend from the substrate 21 toward the +Y direction. The projection shape of the single pillar 22A in the second direction is a rectangle having a long side of 50 μm and a wide side of 40 μm. As for the adjacent pillar 22A, the nearest distance between the two long sides of pillar 22A (i.e., V line segment shown in FIG. 4, is also referred to as pillars distance). The pillars distance can be configured to be 15 μm to 50 μm, preferably 20 μm to 40 μm, and the best mode is 30 μm. The thickness of the substrate 21 may range from 1 mm to 3 mm, and preferably 2 mm. The pillar 22A and the fluidic channel are made of a material to be non-adhesive to the blood cells, for prevent the blood cells from sticking to the pillar 22A or the substrate 21 to affect the screening result. In the present invention, the material of the pillar 22A includes polydimethylsiloxane (PDMS). PDMS is a macromolecule organic silicon compound, and usually referred to as organosilicon. The substrate 21 is made of glass or acrylic material. The pillar 22A made of CONCRETE PDMS 47 and the substrate 21 are connected by a bonding process to constitute the passage 20. The space between two pillar 22A (two rectangles) forms a fluidic channel for conducting any fluid.

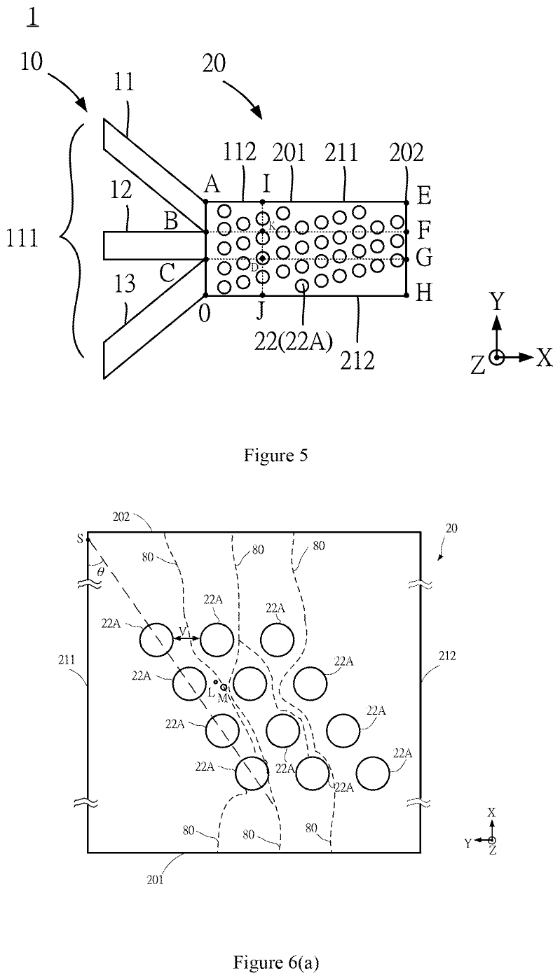

Next, please refer to FIG. 5. FIG. 5 is a partial view showing the WBC filter 1 on the first plane. The screening mechanism of the WBC filter 1 will be described later by referring to FIG. 5. Firstly, the whole blood and the buffer solution are introduced into the passage 20 from the entrance respectively by a driving force. The driving force sources from an external pump (not shown in FIG. 5) connected to the WBC filter 1 to introduce the whole blood and the buffer solution into the passage 20. In this embodiment, after the WBC filter 1 is connected to the external pump, the injection speeds for whole blood, red blood cell lysis buffer and PBS can achieve 300-800 μl/h, 1000-3000 μl/h, and 1000 μl/h, respectively. The injected whole blood and buffer solution all enter the passage 20, then pass through the gap between the pillar 22A of the passage 20 and reach the output portion 30 (not shown in FIG. 5). The whole blood and the buffer solution are mixed within 5 microseconds after entering the passage 20, and then the mixed solution passes through the passage 20.

Please continue to refer to FIG. 5. In the present invention, injecting n kinds of liquids with different viscosity coefficients generates n laminar flow and n flow paths in the passage 20. In this embodiment, because three kinds of liquid with different viscosity coefficients are injected into the passage 20, three laminar flow and three flow paths are formed. The three flow paths are shown in FIG. 5, wherein the first flow path is an area defined by points A, B, E and F (ABEF); the second flow path is an area defined by points B, C, G, and F; and the third flow path is an area is an area defined by CDHG. Because the liquid injected into the first entrance 11 and the second entrance 12 are buffer solution, the laminar flow of the first flow path and the second flow path are grouped as the buffer solution laminar flow. The purpose of forming laminar flow in the passage 20 is to maintain the buffer solution in the middle of the passage, so that the flow of buffer solution does not disarray and the time for lysing buffer to affect the white blood cells is reduced.

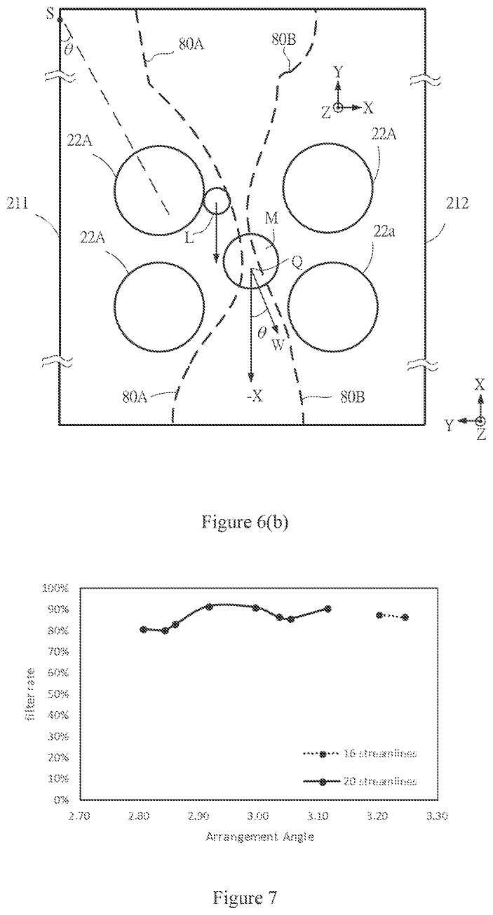

Next, refer to FIG. 5, FIG. 6(a) and FIG. 6(b). Based on the theory of deterministic lateral displacement (hereinafter DLD theory), the blood cells in the whole blood are collided in the area defined by A, B, C, D, J, I point, and the large size blood cells enter the buffer solution laminar flow. The detail of DLD theory is explained herein by referring to FIGS. 6(a) and 6(b). DLD theory provides the concept of setting pillars in the passage (also called fluidic channel) for the fluid to traverse the pillars in the passage, so that the pillars can direct the fluid according to the predetermined layout of the pillars (arrangement angle). Moreover, the pillars also allow the fluid to form laminar flow in the passage, which causes various kinds of fluid to form specific number of stream lines in the passage, as the three stream lines represented in FIG. 6(a). In addition, when the laminar flow initially enters the passage 2, it collides with less pillar 22A, thus the flow path segment lines of the laminar flow (i.e., BF line segment and CG line segment) is conspicuous. However, after the laminar flow travels in the passage for a while, it collides with more pillar 22A and makes the pillar 22A to be less conspicuous, resulting in a poor laminar flow. Therefore, the U line segment shown in FIG. 5 is used as the segmenting line for the above-mentioned laminar flow, and as segmenting line to reflect the distribution of pillar 22A in view of the number of pillars 22A.

Please refer to FIG. 6. As shown in FIG. 6(a), in one embodiment, four kinds of fluid having different viscosity coefficients form three stream lines in the passage, and further define four drainage areas. The four kinds of fluid include particles L and particles M. In this embodiment, the center of the particle L is in the area defined by the first stream line and the first side (i.e., the first drainage area). The particle L undergoes in the first drainage area, and at a certain time point, the particle L moves parallel to the −X direction, as indicated by the arrow on the particle L in FIG. 6(b). Currently, the particle L is in Zigzag mode (Z mode). Similarly, the center of the particle M is in the area defined by the first stream line and the second stream line (i.e., the second drainage area), such that the particle M moves along the complementary direction of the pillar arrangement angle. It means that the moving direction of the particle M and the −X direction form an angle of θ degrees, as indicated by the arrow W based on the particle M in FIG. 6(b). Currently, the particle M is in a bumping mode. Controlling the particles to be in the specific flow path and the arrangement angle of the adjustment pillars to achieve the function of particle separation.

When determining the separation ability of a DLD array, it is necessary to define the size of particles to be shifted. Therefore, the diameter threshold (Dt) must be calculated basing on various physical parameters acquired from the WBC filter. When the particle size is larger than Dt, the particle is situated in the bumping mode, and the particle displaces along with the pillars. When the particle size is smaller than Dt, the particle is situated in the Z mode, and the particle does not displace along with many pillars 22A; instead, the moving direction of the particle is parallel to the fluid direction. According to DLD theory, the diameter threshold for screening in the passage can be determined by Equation 1:

$$Dt = \frac{2}{\sqrt{3}} \cdot {( tan θ )}^{- \frac{1}{2}} \cdot V \cdot ɛ \qquad ( Equation 1 )$$

In Equation 1, θ is the arrangement angle. V is the distance between the nearest long sides of two pillars. ε is the reciprocal of the number of stream lines. Therefore, according to Equation 1, it is understood that adjusting θ, V and ε can determine Dt of certain passage.

Refer to FIG. 5. By using Equation 1, researchers can design WBC filters 1 with various selectivity and sizes according to various application purposes. In general, Dt is designed to be 2 to 12 μm. In the best mode of embodiment, Dt is designed to be 8 μm because the average diameter of human white blood cells is 8 μm; and it is used as the screening criterion for white blood cells and red blood cells. In the present invention, the blood cells (in the whole blood) with diameter greater than or equal to 8 μm are referred to as large-size blood cells. When these large-size blood cells collide with the pillar 22A, they are “separated” and thus enter the buffer solution laminar flow. Those blood cells with the diameter less than 8 μm enter the waste liquid laminar flow. Generally, the average diameter of white blood cells in the whole blood is 8 μm, which is larger than red blood cells (7 μm) and platelets (3 μm) in whole blood. In the area formed by the points A, B, C, 0, J, D, K, and I (i.e., ABC0JDKI area), most of the white blood cells (also called the first-part white blood cells) and some larger-size red blood cells (also called the first-part fragment) enter the buffer solution laminar flow. A small part of the red blood cells (also called the second-part fragment), and platelets in the whole blood will enter the waste liquid laminar flow. The second-part fragment entering the waste liquid laminar flow are lysed by the red blood cell lysis buffer to form particulates (e.g. blood lipid) having a small diameter and then continue to flow. The first-part white blood cells have an average diameter of 12 μm; the first-part fragment have an average diameter of 6 μm; the second-part fragment have an average diameter of 5 μm, and the particulates have an average diameter of 3 μm.

Refer further to FIG. 5. Since the passage 20 has less pillar 22A in the ABC0JDKI area, the screening of whole blood in the ABC0JDKI area is considered as the initial screening. The passage 20 has more pillar 22A in the IKDJHGFE area, so the screening of whole blood in this area is considered as the major screening. Similarly, according to DLD theory, when whole blood flows through the IKDJHGFE area, the white blood cells having larger average diameters (also called the second-part white blood cells) and another part of large-size red blood cells (also called the third-part fragment) in the blood enter the buffer solution laminar flow. The red blood cells having smallest diameters (also called the fourth-part fragment) and the particulates formed in the ABC0JDKI area enter the waste liquid laminar flow. Furthermore, the previously described third-part fragment entering the buffer solution laminar flow, are lysed to form particulates by the red blood cell lysis buffer. These particulates move toward the second side 211, and then enter the waste liquid laminar flow. Among these blood cells, the second-part white blood cells have an average diameter of 13 μm; the third-part fragment cells have average diameter of 2 μm; and the fourth-part red blood cells have an average diameter of 1 μm. Finally, in this embodiment, the laminar flow in the first flow path and the second flow path near the first side 211 are buffer solution laminar flow, and the laminar flow of the third flow path adjacent to the second side 211 is waste liquid laminar flow.

Refer further to FIG. 5. Finally, the waste liquid laminar flow collects the particulates formed in the ABC0JDKI area and the IKDJHGFE area, and then forms the waste liquid at the fourth end 202 to further flow to the output unit 30. The buffer solution laminar flow collects the white blood cells in the ABC0JDKI area and the IKDJHGFE area and forms a purified liquid at the fourth end 202, and then flows to the output unit 30. The purified liquid is further conducted to other external devices connected to the output unit 30. Therefore, the number of white blood cells in the purified liquid is more than the number of white blood cells in the waste liquid; and the number of white blood cells is more than the number of red blood cells in the purified liquid. Accordingly, a large amount of white blood cells can be “screened out” from the whole blood through the WBC filter 1.

Refer last to FIG. 7, Table 1 and Equation 1 altogether. FIG. 7 represents the XY curves of the screening rate for white blood cell from different embodiments practicing the present invention. Table 1 represents the screening rate for white blood cell in different embodiments. When one designs such a device, it is necessary to decide the diameter threshold (Dt) first. In order to screen out the target white blood cells, the diameter threshold is set at 8.0 μm. Otherwise, we set the length of the long side in the WBC filter is 25.5 mm. Then, the number of stream lines is decided. Since the number of stream lines varies according to the type and flow rate of the infused solution, the actual number of stream lines is adopted according to the ideal condition for convenience of designing. In one embodiment of the invention, if only two entrances are used to infuse the whole blood and the phosphate buffer solution, 16 stream lines are ideally set, as shown in embodiments 1 and 2. In another embodiment of the invention, if three entrances are used to infuse the whole blood, the phosphate buffer solution, and the whole blood cells lysis buffer, 20 stream lines are ideally set, as shown in embodiments 3 to 10. Lastly, the value of pillars distance is set ranging from 29 to 31, and then Equation 1 is applied to calculate the corresponding angle to complete the design of the passage, in other words, to form the 10 embodiments in Table 1.

As shown in Table 1, with comparison to the traditional passage, the present invention provides pillars array 22 with configured arrangement angle. Therefore, regardless of the number of fluidic channels, it enables the white blood cell screening rate equal to or greater than 70%, which is better than the conventional passages. Furthermore, as shown in FIG. 7, when the arrangement angle is set at 3 degrees, the best white blood cell screening rate is 86%. Additionally, as shown in FIG. 7, regardless of the number of fluidic channels (i.e., entrances), when the arrangement angle is set at 8 to 3.3 degrees, the white blood cell screening rate of the WBC filter 1 is dramatically increased.

TABLE 1
The white blood cell screening rates of different embodiments

| | | | Reciprocal | | |
|---|---|---|---|---|---|
| | | | of Stream | | White |
| Embodi- | Diameter | Pillars | Lines | Arrangement | Blood Cell |
| ment | threshold | Distance | Number | Angle | Screening |
| No. | Dₜ (μm) | V (μm) | ε | θ (degrees) | Rate (%) |
| 1 | 8.0 | 29.10 | 0.06 | 3.240 | 86% |
| 2 | 8.0 | 29.30 | 0.06 | 3.200 | 88% |
| 3 | 8.0 | 29.70 | 0.05 | 3.110 | 90% |
| 4 | 8.0 | 30.00 | 0.05 | 3.050 | 86% |
| 5 | 8.0 | 30.10 | 0.05 | 3.030 | 86% |
| 6 | 8.0 | 30.30 | 0.05 | 2.990 | 91% |
| 7 | 8.0 | 30.70 | 0.05 | 2.920 | 92% |
| 8 | 8.0 | 31.00 | 0.05 | 2.860 | 83% |
| 9 | 8.0 | 31.10 | 0.05 | 2.840 | 80% |
| 10 | 8.0 | 31.30 | 0.05 | 2.800 | 81% |

According to the previously described embodiments, particularly the results shown in FIG. 7, by using the WBC filter 1 provided in the present invention, the white blood cells are not separated from whole blood through centrifuge. The simple structure design of the pillar array 22 are used to introduce the prepared buffer solution, and the only two steps of initial screening and major screening are further performed to precisely separate the white blood cells in the whole blood. The screening accuracy of the WBC filter 1 is increased by 8% to 15% when compared with the conventional one. Furthermore, the small volume of the WBC filter 1 makes it to be a portable device, so that the user can carry it by his/her side.

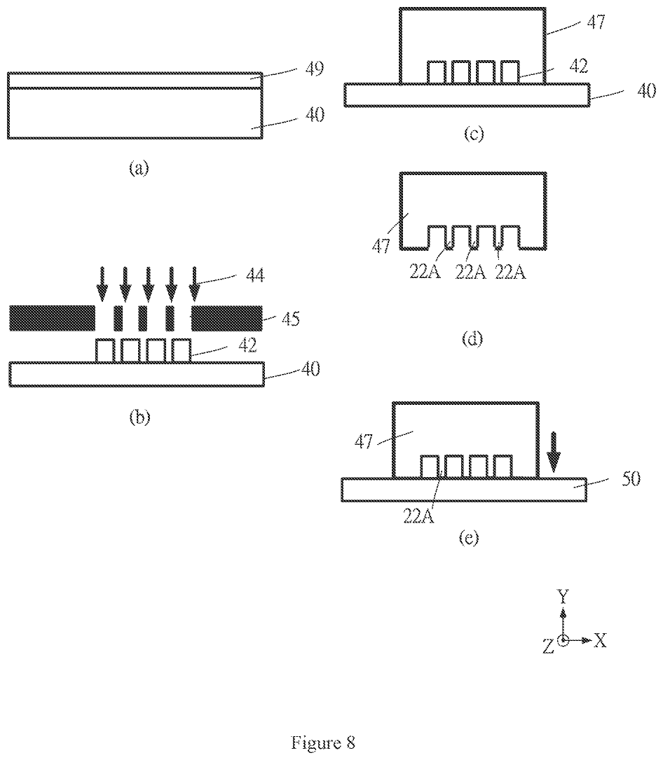

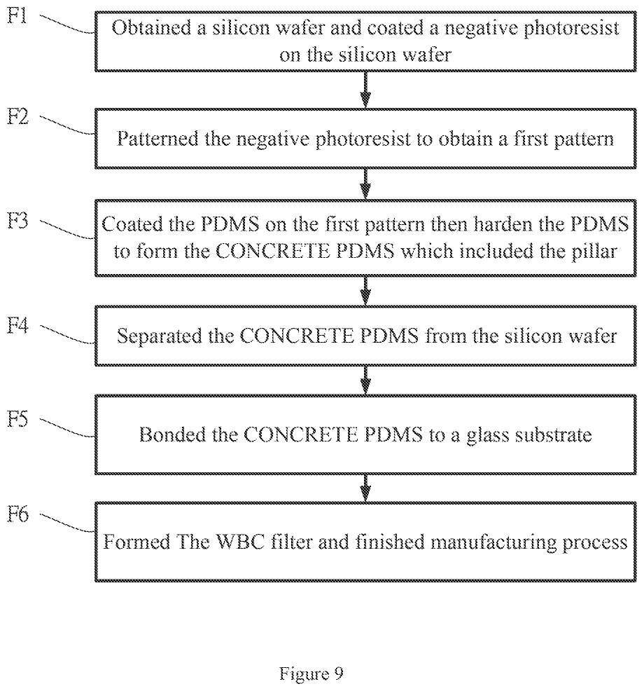

Next, the manufacturing method of the WBC filter 1 are described herein. Please refer to FIGS. 8 and 9 together, which are diagrams for explaining the manufacturing method of the white blood cell filter 1 provided by the present invention. FIG. 8 is a graphical representation, and FIG. 9 is a textual description. Furthermore, FIG. 8 is a schematic diagram drawn on the second plane. Please refer to FIG. 8 and FIG. 9 for the following detailed description:

Step F1: Obtained a silicon wafer 40 coated a negative photoresist 49 on the silicon wafer. Please also refer to FIG. 8(a). The silicon wafer 40 is a silicon wafer and is preferably an n-type doping and <100> direction single crystal silicon wafer. The wafer is then cleaned. The cleaning process is to place the silicon wafer in a cassette, put it into a 120° C. sulfuric acid tank, add 50 ml of hydrogen peroxide and soak for 10 minutes, then soak it in deionized water, wash it until the water resistance reaches 18 MΩ, and then put it into spin dryer to spin dry it. The purpose of this cleaning process is to remove grease and organic matter from the silicon wafer. After that, spin-coat the SU-8 negative photoresist 49 on the silicon wafer which has been cleaned as described above (not shown in FIG. 2(b)) and set the rotation speed of the rotary machine to 500-3250 rpm according to the data corresponding to the selected resist. Make the negative photoresist 49 to spin-coat to 40 μm thick. The 40 μm-thick photoresist can make pillar have an aspect ratio in a range from 2:1 to 3:1. Next, the silicon wafer coated with the negative photoresist 49 is soft baked using a hot plate, and the temperature and time vary according to the negative photoresist parameter table. At the end, the silicon wafer is removed and allowed to cool to room temperature. The purpose of soft baking is to remove excess solvent in the negative photoresist 49, to enhance the negative photoresist 49 adhesion, and to improve the uniformity of the negative photoresist 49 on the silicon wafer, so that the linewidth of the first mask 43 can be accurately represented on the silicon wafer. Next, proceed with step F2.

Step F2: Patterned the negative photoresist 49 to obtain a first pattern 42. Please also refer to FIG. 8(b). The first mask 43 and the silicon wafer are placed in a nanoimprint lithography system EVG620 for exposure. The light source (not shown in FIG. 8(b)) generate rays 44, and the rays 44 is passed through the first mask 43 to reach the negative photoresist 49, wherein the light source is composed of a mercury lamp. The exposure time is adjusted in accordance with the size of the light source and the pillar 22A, and the frequency used for the exposure is the G-Line generated by the mercury lamp. Then, the exposed silicon wafer is placed on a hot plate for baking, and the baking temperature and time vary according to the selected different negative photoresist 49 parameter tables. In the present embodiment, the post-exposure bake was carried out at 200° C. for 10 seconds under a nitrogen atmosphere. The purpose of baking after exposure is to promote the thermal diffusion of the decomposed and un-decomposed photosensitive compounds which are originally distributed according to different interference conditions and eliminate the standing wave effect that may be encountered after exposure, so that the exposed negative photoresist 49 and the unexposed negative photoresist 49 reach higher etching ratio when immersed in the developer. Finally, after the exposed baked wafer is cooled to room temperature, it is immersed in SU-8 developer for development to form a first pattern 42. The development time is adjusted according to the height, and after this procedure is completed, it was treated with deionized water, and gently dried with a nitrogen gun to confirm whether the structure was developed by a microscope. Using the first mask 43 provided in this step, the critical dimension of the first pattern 42 (CD, the line segment V in FIG. 4 of the present invention) can be made smaller than 30 μm. Next, proceed with step F3.

Step F3: Coated the PDMS on the first pattern 42, then harden the PDMS to form the CONCRETE PDMS 47 included the pillar 22A. Please also refer to FIG. 8(c). In this step, a cover (not shown in FIG. 8(c)) is placed above the first pattern 42 to form a chamber. After the chamber is evacuated, the liquefied CONCRETE PDMS 47 material is filled into the chamber. Finally, after waiting for ten minutes, the PDMS can harden at room temperature. Since PDMS is a macromolecule polymer biocompatible material, it does not release toxicant after contact with human body, and thus is used in the WBC filter 1 provided by the present invention. Next, proceed with step F4.

Step F4: Separated the CONCRETE PDMS 47 from the silicon wafer 40. Please also refer to FIG. 8(d). Since the viscosity of the CONCRETE PDMS 47 is different from that of the liquid PDMS, the CONCRETE PDMS 47 can be easily separated from the silicon wafer 40 and the cover (not shown in FIG. 8(d)) by the gripping device. Next, proceed with step F5.

Step F5: Bonded the CONCRETE PDMS 47 to a glass substrate 50. Please also refer to FIG. 8(e). Because the white blood cell separating device may be pressed fit, it needs to be fixed to a rigid and sufficiently thick support base. Since the silicon wafer 40 is not suitable for the support base due to the inadequate rigidity, the support base is changed to the glass substrate 50 having a relatively large rigidity. Finally, the CONCRETE PDMS 47 is inverted on the glass substrate 50 so that the surface of the pillar 22A. That is, let the side which contains the pillar 22A face toward the glass substrate 50, as shown in FIG. 8(e), so that the pillar 22A becomes a flow path through which the fluid can pass. In another embodiment, if a better bonding between the CONCRETE PDMS 47 and the glass substrate 50 is demanded, the bonding surface of the glass substrate 50 may be treated with plasma before the bonding the two elements, so that the surface of the glass substrate 50 is roughened to make it more compatible with the CONCRETE PDMS 47. Next, proceed with step F6.

Step F6: Formed the WBC filter 1 and finished the manufacturing process. Please also refer to FIG. 8(d). After the glass substrate 50 is bonded to the CONCRETE PDMS 47, the WBC filter 1 is formed as shown in FIG. 8(d). In another embodiment, other fluid channels may be superimposed on the exposed air surface of the WBC filter 1, or other white blood cell screening materials may be applied, to enhance the white blood cell screening rate.

The method for manufacturing the WBC filter 1 provided by the invention can be completed not only by a simple semiconductor process, but also has a low cost. The device is disposable and avoids the risk of infection of other people caused by repeated use. Moreover, the completed WBC filter 1 is rigid and not easily broken and has no additional burden on the human body during the test procedure. Additionally, the pillar 22A in the WBC filter 1 also have high density and small spacing distance, and thus increase the capture rate of white blood cells and make the WBC filter 1 is economical.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A WBC filter, comprising:
an input unit which includes two entrances, a first end means for injecting a whole blood and a buffer solution;
a passage which a third end connects the second end of the entrance, wherein pluralities of pillars constructed in the passage; and
an output unit connects to a fourth end of the passage, means for conducting a screened liquid and a purified liquid;
wherein the whole blood and the buffer solution are introduced into the passage from the entrance by a driving force, and forms buffer solution laminar flow and waste liquid laminar flow; separates pluralities of large-size blood cells from the whole blood by colliding the pillars, thus the large-size blood cells enter the buffer solution laminar flow;
the large-size blood cells at the buffer solution laminar flow are lysed to form particulates by the red blood cell lysis buffer, and move toward a second side, thus enter the waste liquid laminar flow; and
conducts the buffer solution laminar flow, whereby filters a purified liquid containing large amount of white blood cells.

2. The WBC filter of claim 1, wherein the buffer solution is selected from the group consisting of the PBS or the RBC lysis buffer.

3. The WBC filter of claim 1, wherein the passage on the first plane is a rectangle which long side is in the range of about 15 mm to about 40 mm.

4. The WBC filter of claim 1, wherein the pillar on the first plane is a circle which radius is 50 μm.

5. The WBC filter of claim 4, wherein the two centers in the two circles is distance between 80 μm.

6. The WBC filter of claim 1, further comprising an arrangement angle which is in the range of about 2.8 degrees to about 3.3 degrees.

7. The WBC filter of claim 1, wherein the laminar flow moves paralleled to the first direction.

8. A WBC filter, comprising:
a whole-blood input unit means for injecting a whole blood;
a second entrance, which adjacent to the whole-blood input unit, means for injecting a buffer solution;
a first entrance, which adjacent to the second entrance, means for injecting a PBS;
a passage which a third end connects the second end of the entrance, wherein pillars constructed in the passage; and
an output unit connects to a fourth end of the passage, means for conduct the screened liquid and purified liquid;
wherein the whole blood and the buffer solution are introduced into the passage from the entrance by a driving force;
After pluralities of blood cells in the whole blood collides with the pillar, the blood cells which radius is larger than 8 μm move to a first side and forms a buffer solution laminar flow;
a pluralities of large-size blood cells at the buffer solution laminar flow are lysed to form particulates by the red blood cell lysis buffer, and move toward a second side, then enter the waste liquid laminar flow; and
conducts the buffer solution laminar flow, whereby filters the white blood cells in the whole blood.

9. A method for manufacturing WBC filter, comprising:
Obtained a silicon wafer and coated a negative photoresist on the silicon wafer;
Patterned the negative photoresist to obtain a first pattern:
Coated the PDMS on the first pattern then harden the PDMS to form the CONCRETE PDMS which included a pillar array;
Separated the CONCRETE PDMS from the silicon wafer;
Bonded the CONCRETE PDMS to a glass substrate and formed The WBC filter.

10. The method for manufacturing WBC filter of claim 9, the critical dimension in the pillar array is 30 μm.

11. A method for manufacturing WBC filter, comprising:
Obtained a silicon wafer and coated a negative photoresist on the silicon wafer;
Patterned the negative photoresist to obtain a first pattern:
Coated the PDMS on the first pattern then harden the PDMS to form the CONCRETE PDMS which included pluralities of pillars;
Separated the CONCRETE PDMS from the silicon wafer, Bonded the CONCRETE PDMS to a glass substrate and formed The WBC filter;
Wherein the pillar having an aspect ratio which is in the range of about 2:1 to about 3:1.
